(19) United States
(12) Patent Application Publication
(10) Pub. No.: US 2026/0164702 A1
(43) Pub. Date: Jun. 11, 2026

(54) NANOSHEET TRIMMING BY DIFFUSION FROM SACRIFICIAL LAYER

(71) Applicant: INTERNATIONAL BUSINESS MACHINES CORPORATION, Armonk, NY (US)

(72) Inventors: Trevor McDonough, Halfmoon, NY (US); Pietro Montanini, Albany, NY (US); Christopher D. Sheraw, Altamont, NY (US); Curtis Scott Durfee, Schenectady, NY (US); Mohamed Abdelmaksoud Mohamed Rabie, Clifton Park, NY (US); Julien Frougier, Albany, NY (US)

(21) Appl. No.: 18/975,028

(22) Filed: Dec. 10, 2024

(51) Int. Cl. H10D 30/00; H10D 30/01

(52) U.S. Cl. CPC H10D 30/503; H10D 30/0193

(57) ABSTRACT

A semiconductor device includes a substrate including a subfin portion having a sheet width and nanosheet channels disposed over the subfin portion. The nanosheet channels each include a central portion having a first thickness and extension regions having a second thickness greater than the first thickness. The central portion and the extension regions form a dogbone shape in cross-section. A sheet width of each of the nanosheet channels remains free of trim erosion and is substantially equal to the sheet width of a corresponding subfin portion of the substrate.

### BACKGROUND

The present invention generally relates to semiconductor devices and processing methods, and more particularly to devices including preserved nanosheet dimensions for device channels by employing diffusion of a dopants from a sacrificial layer.

Semiconductor devices include device channels. The device channels can employ multiple nanosheets to form a channel or channels between source/drain regions of a field effect transistor (FET) device. During nanosheet fabrication processes, active region narrowing may occur as a result of channel release and trimming operations. This narrowing can limit the achievable active region pitch and may impact device performance. The trimming process used to define nanosheet dimensions may cause unintended reduction in the width of active regions. This narrowing effect may become more pronounced as device scaling continues to smaller nodes.

To address potential issues arising from active region narrowing, process tuning may be employed to compensate for material loss during trimming steps. In some cases, the initial dimensions of nanosheet structures may be adjusted to account for expected narrowing. This can include depositing slightly wider initial structures that will be trimmed down to the target dimensions. The compensation for material loss to minimize undesired narrowing effects includes additional processing steps. In some cases, multi-step trimming and compensation processes with varying conditions are needed to achieve proper performance. These additional trimming and compensation processes add to the complexity and expense of device fabrication.

As device scaling continues, active region narrowing and achievable pitch becomes more of an issue as loss of channel dimensions can greatly impact device performance.

### SUMMARY

In accordance with an embodiment of the present invention, a semiconductor device includes a substrate including a subfin portion having a sheet width and nanosheet channels disposed over the subfin portion. The nanosheet channels each include a central portion having a first thickness and extension regions having a second thickness greater than the first thickness. The central portion and the extension regions form a dogbone shape in cross-section. A sheet width of each of the nanosheet channels remains free of trim erosion and is substantially equal to the sheet width of a corresponding subfin portion of the substrate.

In other embodiments, the nanosheet channels can include at least two nanosheet channels vertically stacked above the corresponding subfin portion. The extension regions can be located adjacent to inner spacers. The central portion can include a smooth transition to end portions in the extension regions. The central portion can include rounded edges. A topmost nanosheet channel can include a central portion and extension regions that have a coplanar top surface. The central portion of the topmost nanosheet channel includes a same thickness as the nanosheet channels.

In accordance with another embodiment of the present invention, a semiconductor device includes a substrate having a subfin portion and nanosheet channels which share a footprint with the subfin portion. Each nanosheet channel includes a central portion having a first thickness and extension regions having a second thickness greater than the first thickness. The central portion and the extension regions form a dogbone shape in cross-section. The central portion has edges transversely disposed to a longitudinal axis of a gate structure, the edges having center to edge uniformity being free of trim erosion. A sheet width of each nanosheet channel remains substantially equal to a width of the subfin portion.

In other embodiments, the nanosheet channels can be vertically stacked above a corresponding subfin portion. The extension regions can be located adjacent to inner spacers. The central portion can include a smooth transition to end portions in the extension regions. The edges can include rounded edges. A topmost nanosheet channel can include a central portion and extension regions that have a coplanar top surface. The central portion of the topmost nanosheet channel can include a same thickness as the nanosheet channels.

In accordance with another embodiment of the present invention, a method of fabricating a semiconductor device includes patterning a nanosheet stack on a substrate, the nanosheet stack including alternating layers of a first semiconductor material and a second semiconductor material; forming inner spacers in the nanosheet stack; diffusing dopants from the second semiconductor material into the first semiconductor material; and selectively etching the second semiconductor material and portions of the first semiconductor material with diffused dopants to release nanosheet channels of the first semiconductor material wherein the selectively etching maintains a sheet width of the nanosheet channels that is substantially equal to a width of a corresponding subfin portion of the substrate.

In other embodiments, diffusing dopants can include performing a thermal anneal process. The selectively etching can etch a smooth transition between a central portion and end portions in extension regions of the nanosheet channels. The selectively etching can concurrently trim the nanosheet channels. The nanosheet channels can include a central portion having edges transversely disposed to a longitudinal axis of a gate structure, the edges having center to edge uniformity and are free of trim erosion. The edges can be etched to form rounded edges.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows a top layout view of a substrate having a gate structure disposed thereon, the substrate including a subfin portion having a sheet width, in accordance with an embodiment of the present invention;

FIG. 2 shows cross-section views taken at section lines X and Y of FIG. 1 showing a nanosheet patterned using a hard mask with spacers and inner spacers formed, in accordance with an embodiment of the present invention;

FIG. 3 shows cross-section views taken at section lines X and Y of FIG. 1 showing a thermal diffusion process to drive dopants into nanosheet channel layers and showing Detail A depicting a region around an inner spacer in greater detail, in accordance with an embodiment of the present invention;

FIG. 4 shows cross-section views taken at section lines X and Y of FIG. 1 showing source and drain regions formed, in accordance with an embodiment of the present invention;

FIG. 5 shows cross-section views taken at section lines X and Y of FIG. 1 showing dummy gate material removed, in accordance with an embodiment of the present invention;

FIG. 6 shows cross-section views taken at section lines X and Y of FIG. 1 showing a dummy dielectric layer removed, in accordance with an embodiment of the present invention;

FIG. 7 shows cross-section views taken at section lines X and Y of FIG. 1 showing a channel release process, which includes a selective etch that concurrently removes dopant donor semiconductor layers and dopant diffused regions in the nanosheet channel layer to provide fully formed nanosheet channels in a single step, in accordance with an embodiment of the present invention;

FIG. 8 shows cross-section views taken at section lines X and Y of FIG. 1 showing a topmost nanosheet channel layer having a half thickness, in accordance with an embodiment of the present invention;

FIG. 9 shows cross-section views taken at section lines X and Y of FIG. 1 showing the topmost nanosheet channel layer having a bottom portion etched, in accordance with an embodiment of the present invention;

FIG. 10 shows cross-section views taken at section lines X and Y of FIG. 1 showing a topmost nanosheet channel layer etched to from a top surface to achieve a same thickness of a central portion of a topmost nanosheet channel as other nanosheet channels, in accordance with an embodiment of the present invention; and

FIG. 11 is a perspective view with layers removed to expose a nanosheet channel, the nanosheet channel showing edges of a central portion maintaining a sheet width and being free from trim erosion, in accordance with an embodiment of the present invention.

### DETAILED DESCRIPTION

In accordance with embodiments of the present invention, devices and methods are described which address loss of channel dimensions due to nanosheet processing. In accordance with embodiments of the present invention, a nanosheet stack includes alternating layers of the silicon (Si) and silicon germanium (SiGe). The nanosheet stack is patterned and processed through the formation of inner spacers. The inner spacers include recessing end portions of sacrificial semiconductor layers (SiGe) and filling in formed recesses with dielectric materials. The nanosheet stack is subjected to an anneal process, which is employed while adjacent semiconductor layers (Si and SiGe) of the nanosheet stack remain in contact. The anneal process results in Ge diffusing into the Si semiconductor layers. Since the sacrificial semiconductor (SiGe) layers contact tops and bottoms of the semiconductor (Si) layers, the Ge diffuses into a thickness of the semiconductor (Si) layers.

During a channel release, where the sacrificial semiconductor (SiGe) layers are removed from the nanosheet stack by a selective etch that is selective to the semiconductor (Si) layers of the nanosheet stack. The nanosheets (channels) are concurrently released and trimmed as the Ge containing material of the Si layers is removed as well. This removes a thickness of the Si layers (e.g., making a dogbone structure). The diffused Ge in the Si layers of the nanosheet stack permits slight etching of the Si layers with diffused Ge. The diffusion of the Ge can be controlled to permit mass transfer of the Ge in depth and concentration so that the channel layers are precision etched to provide the trimmed dimensions without excessive dimensional loss of the channel layers. This permits thinning of the channel layers as the Ge diffuses into a depth of the channel layers.

End portions of gate faces maintain a predominantly Si structure and therefore resist the etchants during the channel release to substantially maintain the dimensions of the Si layers along gate structures. Further, in this way, a nanosheet trim process can be omitted as desired dimensions of the Si layers are achieved during the channel release operation. The Si layers of the channel have their subfin width of a subfin portion preserved relative to a sheet width. In an embodiment, the sheet width is a dimension along a gate structure (along a longitudinal gate direction). The sheet width remains substantially equal to a width of a subfin even after trimming. In a cross gate direction, an active portion of the nanosheets have a thickness less than a thickness of extended portions located between inner spacers.

In accordance with embodiments of the present invention, trimming is performed in a vertical direction without trimming laterally (e.g., RX narrowing). The diffusion of the present approach is to functionally reduce the thickness of the nanosheets by causing the existing sacrificial semiconductor layer to expand to have more material removed when the channels are released in a channel release process. This enables achieving target sheet thickness and suspension size without needing inner spacers covering an entire suspension region. Further, reductions in parasitic capacitance and necessary pitch can be achieved.

In an embodiment, two or more nanosheet channels of at least one nanosheet field effect transistor (FET) are disposed on a substrate. The nanosheet channels are thinner in an active region than in an extension region providing a dogbone shape or structure. End portions of the nanosheet channels can include rectangular or rounded portions or shapes as a nanosheet profile with a nanosheet width comparable to subfin width. The dogbone structure of lower nanosheets can include a half dogbone (etched on one side) or an optional full-dogbone on a top sheet.

In accordance with an embodiment of the present invention, a semiconductor device includes a substrate including a subfin portion having a sheet width and nanosheet channels disposed over the subfin portion. The nanosheet channels each include a central portion having a first thickness and extension regions having a second thickness greater than the first thickness. The central portion and the extension regions form a dogbone shape in cross-section. A sheet width of each of the nanosheet channels remains free of trim erosion and is substantially equal to the sheet width of a corresponding subfin portion of the substrate.

In other embodiments, the nanosheet channels can include at least two nanosheet channels vertically stacked above the corresponding subfin portion. The extension regions can be located adjacent to inner spacers. The central portion can include a smooth transition to end portions in the extension regions. The central portion can include rounded edges. A topmost nanosheet channel can include a central portion and extension regions that have a coplanar top surface. The central portion of the topmost nanosheet channel includes a same thickness as the nanosheet channels.

In accordance with another embodiment of the present invention, a semiconductor device includes a substrate having a subfin portion and nanosheet channels which share a footprint with the subfin portion. Each nanosheet channel includes a central portion having a first thickness and extension regions having a second thickness greater than the first thickness. The central portion and the extension regions form a dogbone shape in cross-section. The central portion has edges transversely disposed to a longitudinal axis of a gate structure, the edges having center to edge uniformity being free of trim erosion. A sheet width of each nanosheet channel remains substantially equal to a width of the subfin portion.

In other embodiments, the nanosheet channels can be vertically stacked above a corresponding subfin portion. The extension regions can be located adjacent to inner spacers. The central portion can include a smooth transition to end portions in the extension regions. The edges can include rounded edges. A topmost nanosheet channel can include a central portion and extension regions that have a coplanar top surface. The central portion of the topmost nanosheet channel can include a same thickness as the nanosheet channels.

In accordance with other embodiments, a method for fabricating a semiconductor device includes forming a nanosheet stack (including alternating layers of semiconductor materials) and patterning the nanosheet stack to form fins. Shallow trench isolation (STI) regions are formed about the nanosheet stack as patterned. Inner spacers are formed in the patterned nanosheet stack by recessing alternating layers of the nanosheet stack with an etch process and depositing a dielectric in recesses formed by the etch process.

A thermal diffusion process is performed to permit diffusion of the dopants (e.g., Ge) from one type of alternating layer of the nanosheet stack into the other type (e.g., Si) of alternating layers in the nanosheet stack. S/D regions are formed. The nanosheet stack is revealed by removing dielectric materials covering the nanosheet stack (e.g., polysilicon, dummy oxides, etc.). A channel release is performed that removes alternating layers to expose nanosheet channel layers. The channel release in accordance with embodiment of the present invention can concurrently include a trim process such that the channel release also etches portions of the nanosheet channels to provide a final shape without a separate trim process. It should be understood that an optional anisotropic etch can be performed to create a dogbone on a top sheet and a short isotropic etch can be performed to round the nanosheets. These optional etch processes are less aggressive and do not significantly impact the dimensions of the nanosheet channels. The processing continues with gate formation and device completion.

In accordance with another embodiment of the present invention, a method of fabricating a semiconductor device includes patterning a nanosheet stack on a substrate, the nanosheet stack including alternating layers of a first semiconductor material and a second semiconductor material; forming inner spacers in the nanosheet stack; diffusing dopants from the second semiconductor material into the first semiconductor material; and selectively etching the second semiconductor material and portions of the first semiconductor material with diffused dopants to release nanosheet channels of the first semiconductor material wherein the selectively etching maintains a sheet width of the nanosheet channels that is substantially equal to a width of a corresponding subfin portion of the substrate.

In other embodiments, diffusing dopants can include performing a thermal anneal process. The selectively etching can etch a smooth transition between a central portion and end portions in extension regions of the nanosheet channels. The selectively etching can concurrently trim the nanosheet channels. The nanosheet channels can include a central portion having edges transversely disposed to a longitudinal axis of a gate structure, the edges having center to edge uniformity and are free of trim erosion. The edges can be etched to form rounded edges.

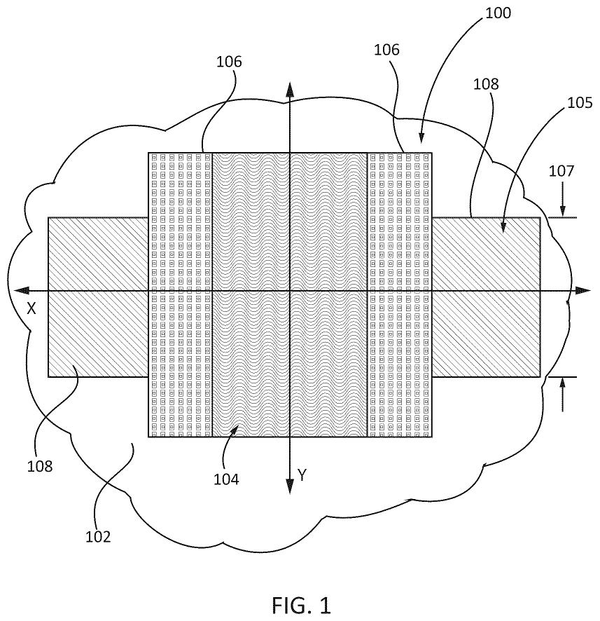

Referring now to the drawings in which like-numerals represent the same or similar elements and initially to FIG. 1, devices and methods for manufacturing a semiconductor device are shown in accordance with embodiments of the present invention. A semiconductor device 100 includes a substrate 102 on which the semiconductor device 100 will be fabricated.

FIG. 1 depicts a top view of a gate 104 with section lines X and Y. Cross-section Y extends along a longitudinal axis of the gate 104 while cross-section X extends across the gate 104 and through source/drain (S/D) regions 108 on opposite sides of the gate 104. The S/D regions 108 are formed over a subfin portion 105 on the substrate 102 having a footprint with a sheet width 107. Spacers 106 are shown for reference. Corresponding X and Y views are depicted throughout the FIGS.

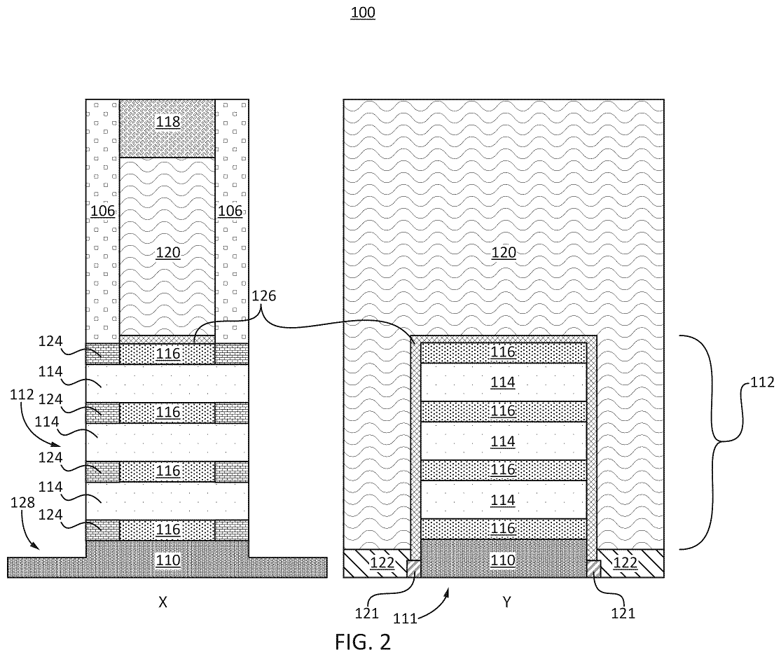

Referring to FIG. 2, sections X and Y show a substrate 110 on which the semiconductor device 100 will be fabricated. The substrate 110 can include any suitable substrate structure, e.g., a bulk semiconductor, a semiconductor-on-insulator (SOI) substrate, etc., and preferably includes a monocrystalline semiconductor. In one example, the substrate 110 can include a silicon-containing material. Illustrative examples of Si-containing materials suitable for the substrate 110 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

A nanosheet stack 112 is applied to or formed on the substrate 110. In an embodiment, nanosheets can be epitaxially grown using different chemistries to form layers having different properties. In an embodiment, the nanosheet stack 112 includes alternating layers of semiconductor layers 114 forming nanosheets and sacrificial semiconductor layers 116.

Each of the semiconductor layers 114 and the sacrificial semiconductor layers 116 are selectively removeable relative to each other, e.g., by a selective etching process. In an embodiment, the sacrificial semiconductor layers 116 can include SiGe, where Ge can be between about 30-55 atomic % of the compound. The semiconductor layers 114 can include Si. It should be understood that other materials or atomic percentages can be employed for the semiconductor layers 114 and the sacrificial semiconductor layers 116. In other embodiments, different stack orders and numbers may be employed for semiconductor layers 114 and the sacrificial semiconductor layers 116.

A dummy dielectric layer 126 can be formed over the nanosheet stack 112 by a deposition process, e.g., chemical vapor deposition (CVD) or atomic layer deposition (ALD). The dummy dielectric layer 126 can include an oxide.

A dummy gate material 120 is blanketed over the nanosheet stack 112 followed by a blanket deposition of a hard mask material to later form a hard mask 118 e.g., by using photolithographic patterning. The dummy gate material 120 can include a polysilicon, amorphous Si or other selectively removeable material. The hard mask 118 is employed to etch the dummy gate material 120 and the dummy dielectric layer 126. Then, a deposition process is employed to form spacers 106. Spacers 106 can include an oxide, such as silicon dioxide, although other dielectric materials can be employed.

The hard mask 118 and spacers 106 can be employed as an etch mask to recess the nanosheet stack 112 to expose the substrate 110. The hard mask 118 and spacers 106 can be employed to continue to etch into the substrate 110 to form recesses 128. Regions of the nanosheet stack 112 below the hard mask 118 and spacers 106 are patterned for further processing including etching trenches, e.g., by reactive ion etching (RIE) in the substrate 110 and filling the trenches with dielectric material (e.g., a shallow trench isolation liner 121 and shallow trench isolation (STI) material)) and recess etching the dielectric material to form STI regions 122. A subfin 111 forms a part of the substrate 110 and includes a size and shape corresponding to a footprint of the nanosheet stack 112 as originally patterned in a nanosheet stack.

Inner spacers 124 are formed and include a dielectric material. In an embodiment, the inner spacers 124 are formed by laterally recessing the sacrificial semiconductor layers 116 by an etch process, followed by a dielectric fill (e.g., a dielectric oxide (SiO₂)) to provide the inner spacers 124.

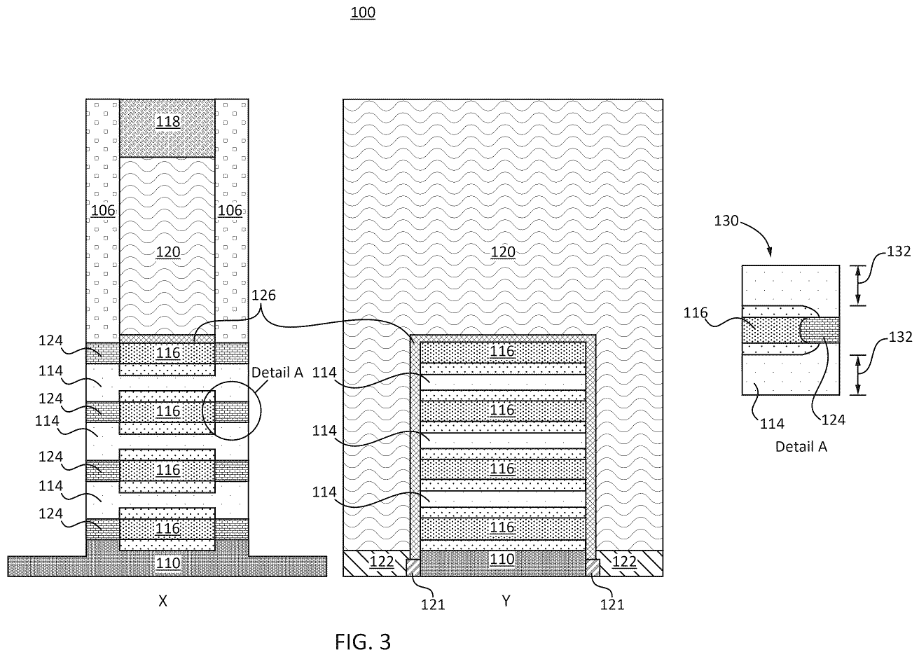

Referring to FIG. 3, a thermal anneal process is employed to diffuse dopants from the sacrificial semiconductor layers 116 into the semiconductor layers 114. In an embodiment, the sacrificial semiconductor layers 116 include SiGe and the semiconductor layers 114 include Si. The thermal anneal process causes diffusion of Ge into the Si of the semiconductor layers 114. The thermal anneal can include a temperature of between about 600 degrees Celsius to about 1000 degrees Celsius. The time and temperature of the thermal anneal will determine the amount of Ge and distance that the Ge penetrates into the Si matrix. The dopant concentration of Ge within the Si will result in a final shape or profile of nanosheet channels formed in later steps.

A diffusion profile 130 shown in Detail A depicts Ge atoms diffusing into thicknesses 132 of the semiconductor layers 114 and forming a dogbone shaped profile for the diffusion profile 130. The diffusion profile 130 includes less Ge (slower) penetration at end portions near the inner spacers 124. The introduction of Ge atoms into the Si of the semiconductor layers 114 makes portions of the diffusion profile 130 containing Ge selectively etchable relative to regions of the semiconductor layers 114 having a higher concentration of Si.

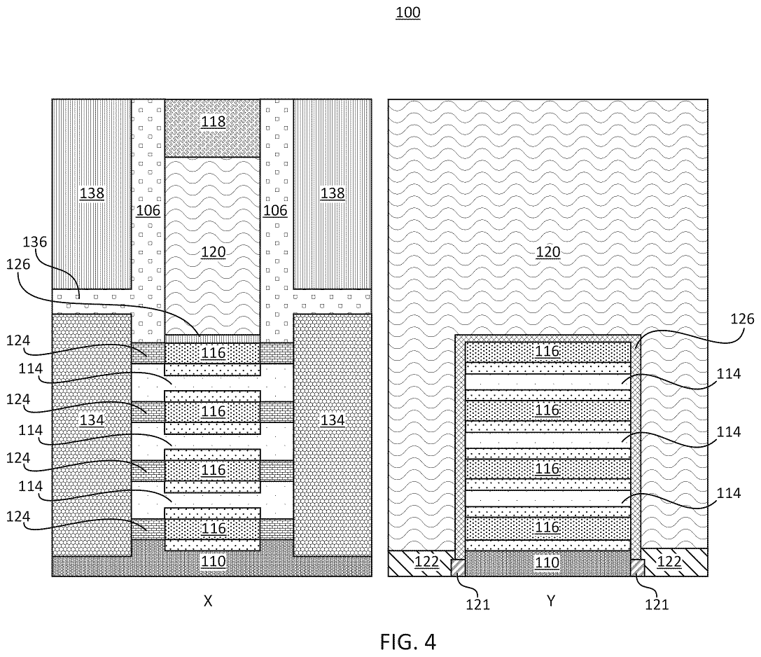

Referring to FIG. 4, an epitaxial growth process is performed to form S/D regions 134. Epitaxial growth can be initiated on the substrate 110 in the recesses 128 and exposed portions of the semiconductor layer 114. S/D regions 134 are employed to form field effect transistors (FET) for the semiconductor device 100. Depending on a device type (e.g., N-type or P-type), S/D regions 134 can include Si or SiGe. For example, if the S/D regions 134 include N-type devices then the S/D regions 134 can include Si. In another example, if the S/D regions 134 include P-type devices then the S/D regions 134 can include SiGe. The S/D regions 134 can be appropriately doped during formation by epitaxial growth. For example, the S/D regions 134 can be doped by introducing p dopants (e.g., B, Ga, etc.) during epitaxial formation. Similarly, the S/D regions 134 can be doped by introducing n dopants (e.g., P, As, etc.) during epitaxial formation.

A spacer layer 136 is formed over the S/D regions 134 followed by a dielectric layer 138, such as, e.g., an interlevel dielectric layer (ILD). The spacer layer 136 can provide a selectively etchable material relative to the dielectric layer 138. The spacer layer 136 and the dielectric layer 138 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α—C:H). The spacer layer 136 and the dielectric layer 138 can be deposited using CVD, although other deposition methods can be employed.

The dielectric layer 138 is then recessed by an etch back process that removes the dielectric layer 138 evenly (level) across the semiconductor device 100.

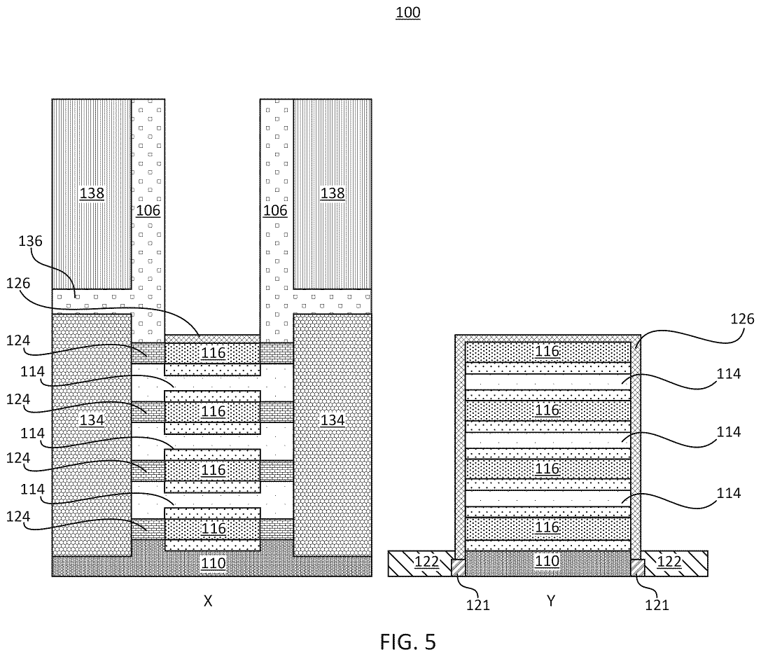

Referring to FIG. 5, the hard mask 118 is removed followed by the removal of the dummy gate material 120. The hard mask 118 and the dummy gate material 120 can be removed by a combination of selective etching processes or a combination of planarization and etch processes.

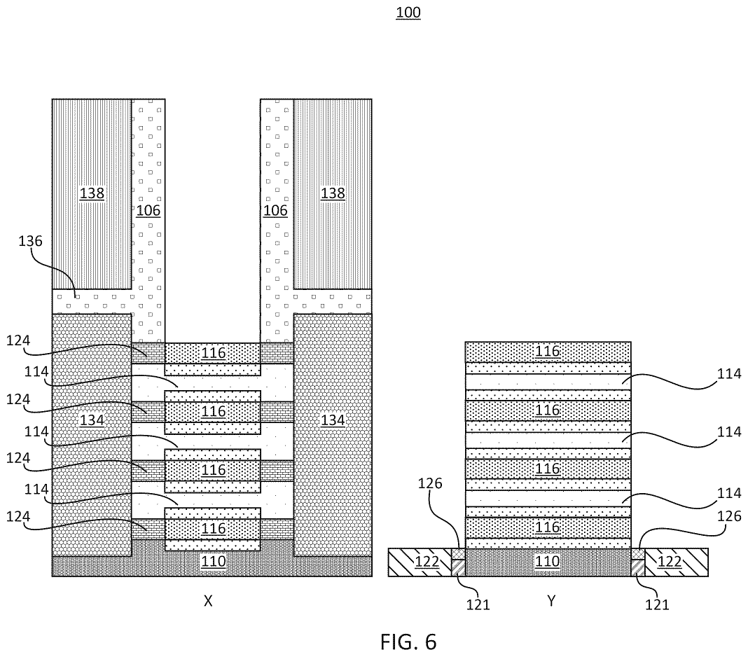

Referring to FIG. 6, the dummy dielectric layer 126 is removed to expose the semiconductor layers 114 and the sacrificial semiconductor layers 116.

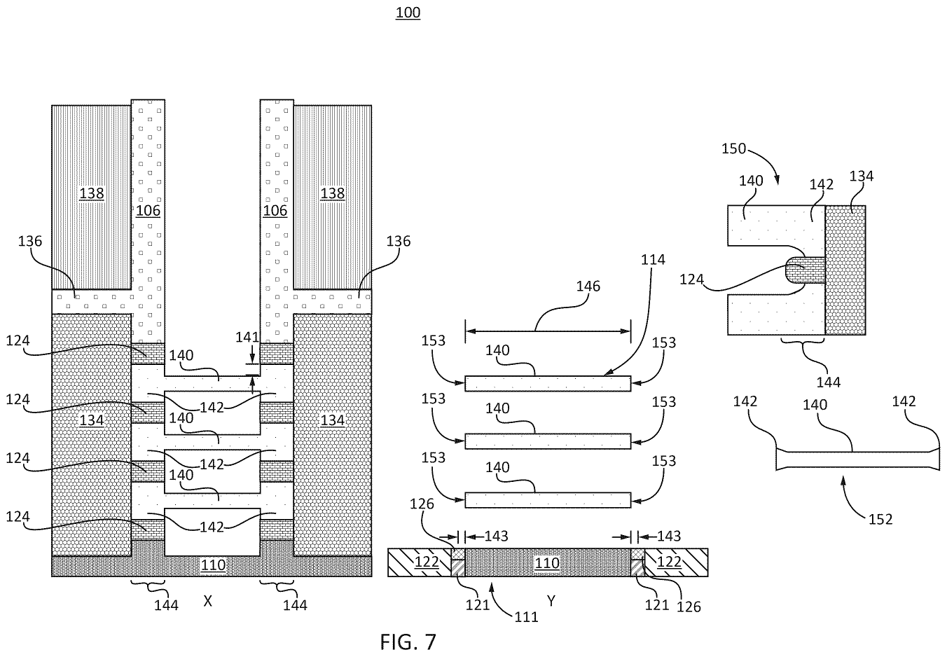

Referring to FIG. 7, a channel release process is performed. The channel release process includes a selective etch to remove the sacrificial semiconductor layers 116 to leave the semiconductor layers 114 to form nanosheet channels 140. A supplementary trim process may also be performed to fine tune dimensions (e.g., to form a dogbone shape).

In an embodiment, the selective etch removes SiGe materials selectively to Si materials. As a result of thermal annealing, Ge dopants diffused into the Si of the semiconductor layers 114 cause the etch process to shape the nanosheet channels 140 that result from the etch. The etch process thins the nanosheet channels 140 in a central portion from a thickness of the semiconductor layers 114 in extension regions 144. This provides the dogbone shape.

In accordance with embodiments of the present invention, a sheet width 146 of the nanosheet channels 140 is preserved during the selective etch process. Since the selective etch process is highly selective, the Si material of the nanosheet channels 140 remains virtually unchanged. This means that the rounding and erosion of the nanosheet channels 140 at end portions 153 is halted and there is no loss of the sheet width 146. Said differently, the subfin 111 (which is unetched) and the nanosheet channels 140 have a sheet width 146 that is the same dimension (or substantially the same dimension).

The selective etch etches a sheet thickness indicated by a thickness loss 141 (e.g., ΔT) on tops and bottoms of the nanosheet channels 140 and etches the sheet width 146 by a width loss 143 (e.g., (ΔW)) of the nanosheet channels 140. The width loss 143 of the sheet width 146 is minimized in accordance with embodiments of the present invention. Any loss in the sheet width 146 is undesirable. In embodiments of the present invention, the width loss 143 is near zero. The width loss 143 can be measured against the subfin 111. The subfin 111 and the channel nanosheet channels 140 in the extension regions 144 are protected by the inner spacers 124 and the STI regions 122 and the STI liner 121, so there is no loss or virtually no loss during the selective etch. As a result, the shape 152 can include a dogbone profile, shown in both X and Y views.

Embodiments of the present invention provide the width loss 143 (ΔW) near zero. Said differently, the width loss 143 can be equal to or less than the thickness loss 141 (ΔT). Inherent loss in the undesired direction (ΔW) (the width loss 143) is minimized (e.g., substantially no loss) being equal to zero or at least meeting the following criteria: ΔT≥ΔW. In other embodiments, the widths of the subfin 111 and nanosheet channels 140 can be considered substantially equal if ΔW≤0.95*ΔT.

A magnified detailed view 150 shows an end profile of as the nanosheet channels 140 at the extension region 144. The thickness of the nanosheet channels 140 transitions to a full thickness in end portions 142 of the semiconductor layers 114 in the extension region 144, but gets thinner as a remainder of the nanosheet channels 140.

A shape 152 is achieved for the nanosheet channels 140 as a result of the diffusion profile 130 (FIG. 3) and the selective etch. The shape 152 includes gradual or smooth transitions with no shape edges or cusps. The smoothness is controlled in accordance with mass transfer mechanisms. The smooth transitions achieved in accordance with the present embodiments would be difficult or impossible to achieve using a secondary etch process to etch the nanosheet channels.

Since the nanosheet channels 140 and end portions 142 are shaped by the channel release process, a secondary etch process (a trim) can be avoided. The trim process is usually employed to reduce a thickness of nanosheet channels. As a result of such trimming, the sheet width of the nanosheet channel would be diminished, and in some cases, significantly. This can be avoided in accordance with the embodiments of the present invention.

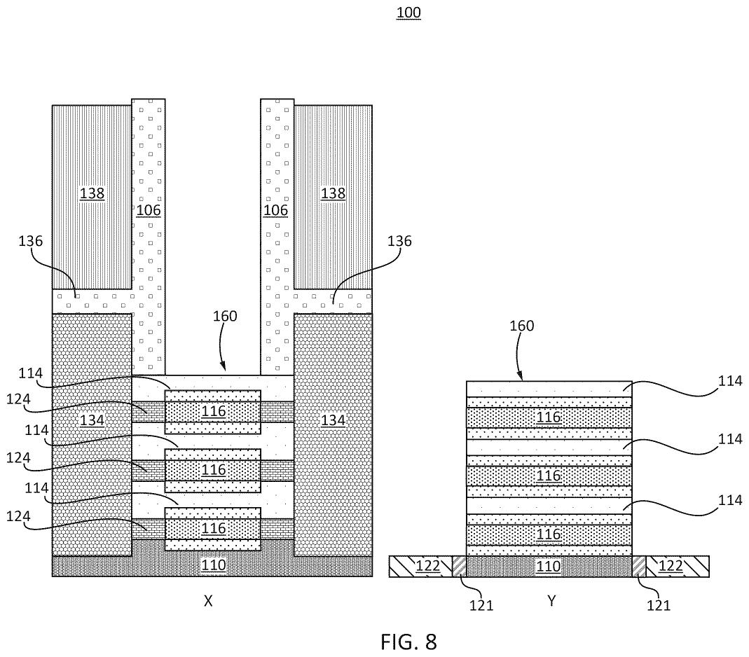

Referring to FIG. 8, in other embodiments, a top nanosheet channel 160 can include a semiconductor layer 114 without the sacrificial semiconductor layer 116 thereon. In such a case, no dopants from the sacrificial semiconductor layers 116 can be employed to dope a top surface of the semiconductor layers 114 to generate a dogbone profile from a top side. Instead, the top nanosheet channel 160 can be provided at half thickness, and a central portion and end portions of the top surface of the top nanosheet channel 160 remain coplanar. Processing of a lower portion of the top nanosheet channel 160 can include diffusing Ge dopants in a lower half of the top nanosheet channel 160 and then selectively etching the nanosheet channels 140 and the top nanosheet channel 160.

In this way, the removal of the doped material from the lower half of the top nanosheet channel 160 can be etched to provide a channel thickness for the top nanosheet channel 160 that is the same thickness as the nanosheet channels 140.

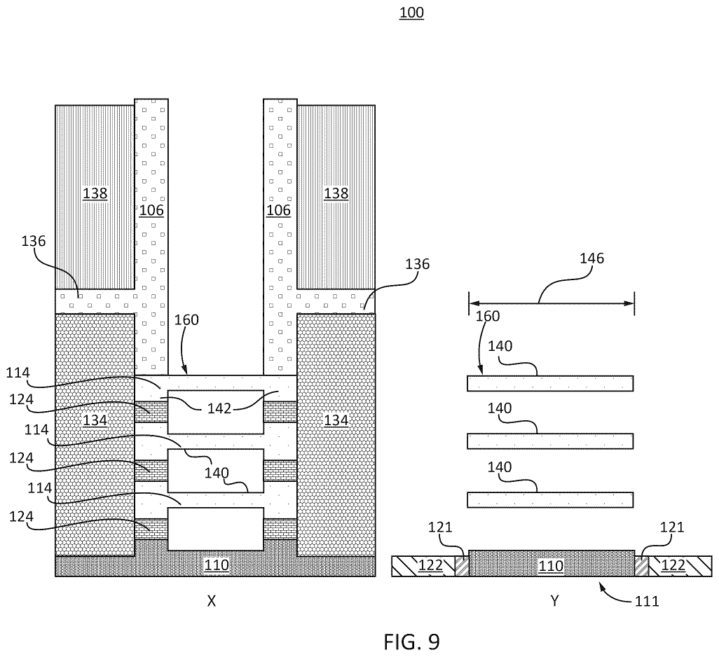

Referring to FIG. 9, after the selective etch, the nanosheet channels 140 and top nanosheet channel 160 include the same thickness. The nanosheet channels 140 and top nanosheet channel 160 are reduced from a size of end portions in the extension regions and, as described, do not experience any significant dimensional loss in the sheet width 146 due to the channel release process.

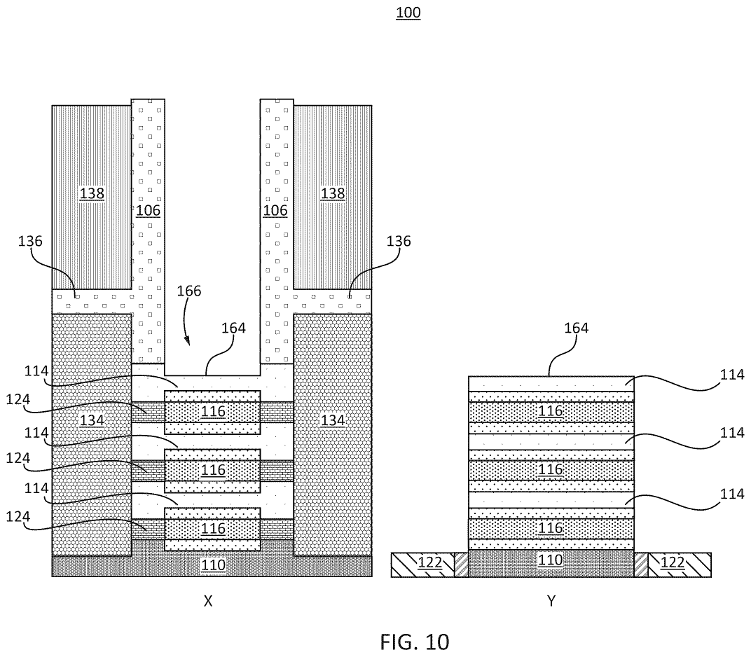

Referring to FIG. 10, in other embodiments, a top nanosheet channel 164 can include a semiconductor layer 114 without a sacrificial semiconductor layer 116 thereon. In such a case, no dopants from the sacrificial semiconductor layer 116 can be employed to dope the semiconductor layer 114 to generate a dogbone profile from a top side. Instead, the top nanosheet channel 164 can be provided at full thickness and etched to form a recess 166 to reduce a top surface. A lower portion of the top nanosheet channel 164 can include diffused Ge dopants in a lower half of the top nanosheet channel 164. Then, selective etching of the nanosheet channels 140 and the top nanosheet channel 164 can be performed together. The resulting structure is similar to that shown in FIG. 7. The separate etching of only the top nanosheet channel 164 avoids any damage to underlying nanosheet channel layers (e.g., the semiconductor layers 114).

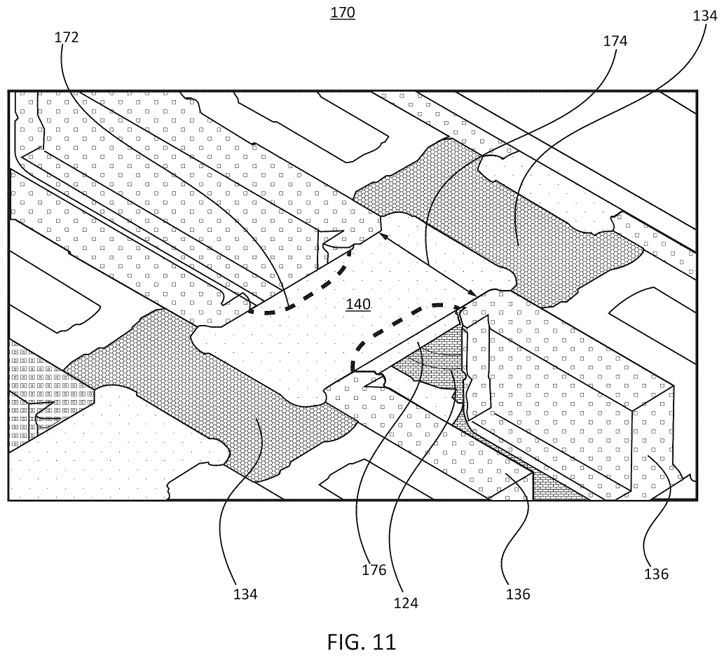

Referring to FIG. 11, a perspective view is shown with material removed to expose one of the nanosheet channels 140 in accordance with an embodiment of the present invention. The nanosheet channels 140 include a sheet width 174 that remains intact or significantly remains intact across a central portion of the nanosheet channels 140 after a channel release process. Diffusing Ge from a sacrificial layer (the sacrificial semiconductor layers 116, FIG. 6) into the nanosheet channels 140 after the inner spacers 124 have been formed, results in trimming during channel release. This eliminates the need for a silicon etch step. Dashed lines 172 illustrate a location where a conventional secondary trim etch would erode away part of the nanosheet channels 140. The dashed lines 172 indicate trim erosion, which is common to conventional processes that trim the nanosheet channels after the channel release step (e.g., a secondary etch). The dashed lines 172 indicate low center to edge uniformity as the dashed lines 172 indicate a curved surface. In accordance with embodiments of the present invention, the nanosheet channels 140 maintain their shape and boundaries without the erosion depicted by dashed lines 170. Instead, the etching performed as a channel etch results in the desired dimensions of the nanosheet channels 140 and an extremely high center to edge uniformity as edges 176 are parallel to center lines of the nanosheet channels 140.

It should be understood that the edges 176 of the nanosheet channels 140 can include a rectangular shape. In other embodiments, an optional light etch can be performed to round out the edges 176 to form rounded edges and remove corners of the nanosheet channels 140. The light etch can include a short isotropic etch that can be performed to round the nanosheet channels 140. This optional etch process is less aggressive and does not significantly impact the dimensions of the nanosheet channels 140. The processing continues with gate formation and device completion.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods, as described herein, can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a substrate including a subfin portion having a sheet width; and
nanosheet channels disposed over the subfin portion, the nanosheet channels each including:
a central portion having a first thickness; and
extension regions having a second thickness greater than the first thickness, the central portion and the extension regions having a dogbone shape in cross-section, wherein a sheet width of each of the nanosheet channels remains free of trim erosion and substantially equal to the sheet width of a corresponding subfin portion of the substrate.

2. The semiconductor device of claim 1, wherein the nanosheet channels include at least two nanosheet channels vertically stacked above the corresponding subfin portion.

3. The semiconductor device of claim 1, wherein the extension regions are located adjacent to inner spacers.

4. The semiconductor device of claim 1, wherein the central portion includes a smooth transition to end portions in the extension regions.

5. The semiconductor device of claim 1, wherein the central portion includes rounded edges.

6. The semiconductor device of claim 1, wherein a topmost nanosheet channel includes a central portion and extension regions that have a coplanar top surface.

7. The semiconductor device of claim 6, wherein the central portion of the topmost nanosheet channel includes a same thickness as the nanosheet channels.

8. A semiconductor device, comprising:
a substrate having a subfin portion; and
nanosheet channels which share a footprint with the subfin portion wherein each nanosheet channel includes:
a central portion having a first thickness; and
extension regions having a second thickness greater than the first thickness, the central portion and the extension regions having a dogbone shape in cross-section;
the central portion having edges transversely disposed to a longitudinal axis of a gate structure, the edges having center to edge uniformity being free of trim erosion, wherein a sheet width of each nanosheet channel remains substantially equal to a width of the subfin portion.

9. The semiconductor device of claim 8, wherein the nanosheet channels are vertically stacked above a corresponding subfin portion.

10. The semiconductor device of claim 8, wherein the extension regions are located adjacent to inner spacers.

11. The semiconductor device of claim 8, wherein the central portion includes a smooth transition to end portions in the extension regions.

12. The semiconductor device of claim 8, wherein the edges include rounded edges.

13. The semiconductor device of claim 8, wherein a topmost nanosheet channel includes a central portion and extension regions that have a coplanar top surface.

14. The semiconductor device of claim 13, wherein the central portion of the topmost nanosheet channel includes a same thickness as the nanosheet channels.

15. A method of fabricating a semiconductor device, comprising:
patterning a nanosheet stack on a substrate, the nanosheet stack including alternating layers of a first semiconductor material and a second semiconductor material;
forming inner spacers in the nanosheet stack;
diffusing dopants from the second semiconductor material into the first semiconductor material; and
selectively etching the second semiconductor material and portions of the first semiconductor material with diffused dopants to release nanosheet channels of the first semiconductor material wherein the selectively etching maintains a sheet width of the nanosheet channels that is substantially equal to a width of a corresponding subfin portion of the substrate.

16. The method of claim 15, wherein diffusing dopants include performing a thermal anneal process.

17. The method of claim 15, wherein the selectively etching etches a smooth transition between a central portion and end portions in extension regions of the nanosheet channels.

18. The method of claim 15, wherein the selectively etching concurrently trims the nanosheet channels.

19. The method of claim 15, wherein the nanosheet channels includes a central portion having edges transversely disposed to a longitudinal axis of a gate structure, the edges having center to edge uniformity and are free of trim erosion.

20. The method of claim 19, wherein the edges are etched to form rounded edges.
